(19) United States
(12) Patent Application Publication
(10) Pub. No.: US 2026/0305139 A1
(43) Pub. Date: Oct. 1, 2026

(54) DISPLAY PANEL

(71) Applicants: Chengdu BOE Optoelectronics Technology Co., Ltd., Chengdu, Sichuan (CN); BOE Technology Group Co., Ltd., Beijing (CN)

(72) Inventors: Guoyi CUI, Beijing (CN); Tao GAO, Beijing (CN); Bingqiang GUI, Beijing (CN); Ruoxiang LI, Beijing (CN); Yanqiang WANG, Beijing (CN)

(21) Appl. No.: 18/880,575

(22) PCT Filed: May 28, 2024
(86) PCT No.: PCT/CN2024/095784

§ 371 Date: Jan. 2, 2025

(30) Foreign Application Priority Data
May 31, 2023 (CN) 202310639501.3

(51) Int. Cl. H10K 59/80; H10K 59/122; H10K 59/38; H10K 59/40

(52) U.S. Cl. CPC H10K 59/879; H10K 59/122; H10K 59/38; H10K 59/40; H10K 59/873; H10K 59/8792

(57) ABSTRACT

A display panel, comprising: a substrate layer, a driving circuit layer, a pixel layer, a packaging layer, a functional layer, and a filter layer. The functional layer comprises a light extraction structure, a first touch metal structure, and a second touch metal structure; the light extraction structure is disposed on the packaging layer, the projection of the light extraction structure on the substrate layer covers the projection of a light-emitting unit on the substrate layer, the light extraction structure is covered with a first insulating material, and the light refractive index of the light extraction structure is greater than that of the first insulating material; the projections of the first touch metal structure and the second touch metal structure on the substrate layer partially overlap, and the first insulating material is provided between the first touch metal structure and the second touch metal structure.

### CROSS-REFERENCE TO RELATED APPLICATIONS

The present application is a U.S. National Phase Entry of International Application No. PCT/CN2024/095784 having an international filing date of May 28, 2024, which claims priority to Chinese Patent Application No. 202310639501.3 filed to the CNIPA on May 31, 2023, which are hereby incorporated into the present application by reference in their entireties.

### TECHNICAL FIELD

Embodiments of the present disclosure relate to, but are not limited to, the field of display, and more particularly to a display panel.

### BACKGROUND

With the increasing maturity of Organic Light-Emitting Diode (OLED) technology, power reduction and bending requirements have become a new development direction of display panels. However, light efficiency and viewing angle of existing display panels still need to be further improved.

### SUMMARY

The following is a summary of subject matter described in the present disclosure in detail. This summary is not intended to limit the protection scope of claims.

An embodiment of the present disclosure proposes a display panel, including a substrate layer, a drive circuit layer, a pixel layer, an encapsulation layer, a functional layer, and a filter layer. The pixel layer includes a pixel defining layer and a light-emitting unit. The light-emitting unit is connected to a drive circuit of the drive circuit layer, the drive circuit layer is provided on the substrate layer, and the encapsulation layer is provided on the pixel layer. The functional layer includes a light extraction structure, a first touch metal structure, and a second touch metal structure. The light extraction structure is provided on the encapsulation layer, a projection of the light extraction structure on the substrate layer covers a projection of the light-emitting unit on the substrate layer, the light extraction structure is covered with a first insulating material, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material. The filter layer includes a color filter and a black matrix. A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and the color filter and the black matrix are covered with a second insulating material.

In some embodiments, the light extraction structure is provided in a first insulating layer, the first touch metal structure is provided in a second insulating layer, and the second touch metal structure is provided in a third insulating layer. The first insulating layer, the second insulating layer, and the third insulating layer are all formed by the first insulating material.

In some embodiments, the light extraction structure is provided in a first insulating layer, the first touch metal structure is provided in a second insulating layer, the second touch metal structure is provided on the second insulating layer, and the black matrix is covered on the second touch metal structure. The first insulating layer and the second insulating layer are both formed by the first insulating material.

In some embodiments, the first touch metal structure is provided in a first insulating layer, and the light extraction structure and the second touch metal structure are both provided in a second insulating layer. The first insulating layer and the second insulating layer are both formed by the first insulating material.

In some embodiments, the light extraction structure and the first touch metal structure are both provided in a first insulating layer, and the second touch metal structure is provided in a second insulating layer. The first insulating layer and the second insulating layer are both formed by the first insulating material.

In some embodiments, the light extraction structure and the first touch metal structure are both provided in a first insulating layer, the second touch metal structure is provided on the first insulating layer, and the black matrix is covered on the second touch metal structure. The first insulating layer is formed by the first insulating material.

In some embodiments, a material used by the light extraction structure is covered on the first touch metal structure.

In some embodiments, the first insulating material is covered on the first touch metal structure, and a surface of the light extraction structure in contact with the first insulating material is provided with a predetermined pattern.

In some embodiments, an inorganic layer is further provided on the encapsulation layer.

In some embodiments, the light extraction structure has a convex structure, a convex direction of the convex structure faces the filter layer, adjacent light extraction structures are independent from each other, and a projection of the color filter on the substrate layer covers a projection of the light extraction structure on the substrate layer.

In some embodiments, the light extraction structure has a convex structure, a convex direction of the convex structure faces the encapsulation layer, adjacent light extraction structures are connected to each other to form a continuous light extraction structure, a surface of the continuous light extraction structure in contact with the first insulating material is parallel to a first surface of the encapsulation layer, wherein the first surface is a surface close to the filter layer.

In some embodiments, the light extraction structure has a convex structure, a cross section of the convex structure is a trapezoid, and a bottom angle of the trapezoid is greater than 50 degrees and less than 80 degrees.

In some embodiments, the projection of the light extraction structure on the substrate layer is greater than a projection of an opening of the pixel defining layer on the substrate layer.

In some embodiments, a projection of the black matrix on the substrate layer does not overlap with the projection of the light extraction structure on the substrate layer.

In another aspect, an embodiment of the present disclosure proposes an electronic device, including the display panel according to any one of the embodiments of the present disclosure. Other aspects of the present disclosure may be comprehended after the drawings and the detailed descriptions are read and understood.

### BRIEF DESCRIPTION OF DRAWINGS

In order to describe technical solutions in embodiments of the present disclosure or the prior art more clearly, the drawings to be used for describing the embodiments or the prior art will be introduced below in brief. Apparently, the drawings described below are only some embodiments of the present disclosure, and those of ordinary skills in the art may also obtain other drawings according to these drawings without paying any inventive effort.

FIG. 1 is a schematic diagram of a cross-sectional structure of a display panel according to an embodiment of the present disclosure.

FIG. 2 is a schematic diagram of a cross-sectional structure of another display panel according to an embodiment of the present disclosure.

FIG. 3 is a schematic diagram of a cross-sectional structure of yet another display panel according to an embodiment of the present disclosure.

FIG. 4 is a schematic diagram of a cross-sectional structure of yet another display panel according to an embodiment of the present disclosure.

FIG. 5 is a schematic diagram of a cross-sectional structure of yet another display panel according to an embodiment of the present disclosure.

FIG. 6 is a schematic diagram of a cross-sectional structure of yet another display panel according to an embodiment of the present disclosure.

FIG. 7 is a schematic diagram of a cross-sectional structure of yet another display panel according to an embodiment of the present disclosure.

FIG. 8 is a first schematic design diagram of a light extraction structure according to an embodiment of the present disclosure.

FIG. 9 is a schematic diagram of a cross-sectional profile of a light extraction structure according to an embodiment of the present disclosure.

FIG. 10 is a second schematic design diagram of a light extraction structure according to an embodiment of the present disclosure.

### DETAILED DESCRIPTION

In order to make objectives, technical solutions, and advantages of the embodiments of the present disclosure clearer, the technical solutions of the embodiments of the present disclosure will be clearly and completely described below with reference to the drawings of the embodiments of the present disclosure. Apparently, the described embodiments are a part of the embodiments of the present disclosure, not all of the embodiments. Based on the described embodiments of the present disclosure, all other embodiments obtained by those of ordinary skills in the art without paying any inventive effort are within the protection scope of the present disclosure.

Unless otherwise defined, technical terms or scientific terms used in the present disclosure should have the meanings as commonly understood by those of ordinary skills in the art that the present disclosure belongs to. The word “first”, “second” and similar words used in the present disclosure do not indicate any order, quantity, or importance, but are used only for distinguishing different components. “Include”, “contain”, or similar words mean that elements or objects appearing before the words cover elements or objects listed after the words and their equivalents, but do not exclude other elements or objects. “Connect”, “couple”, or similar words are not limited to a physical or mechanical connection, but may include an electrical connection, whether direct or indirect. “Upper”, “lower”, “left”, and “right”, etc., are used for representing a relative positional relationship, and when an absolute position of a described object is changed, the relative positional relationship may also be correspondingly changed.

In order to keep following description of the embodiments of the present disclosure clear and concise, detailed description of known functions and known components are omitted in the present disclosure.

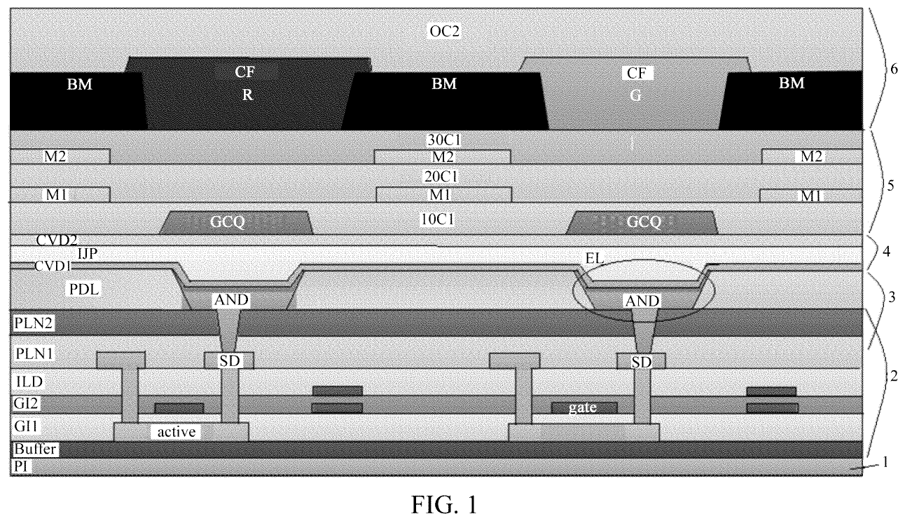

An embodiment of the present disclosure provides a display panel with a cross-sectional structure as shown in FIG. 1. The display panel includes: a substrate layer 1, a drive circuit layer 2, a pixel layer 3, an encapsulation layer 4, a functional layer 5 and a filter layer 6.

The pixel layer includes a Pixel Defining Layer (PDL), and a light-emitting unit (Electron luminescence (EL)).

The light-emitting unit is connected to a drive circuit of the drive circuit layer, the drive circuit layer is provided on the substrate layer, and the encapsulation layer is provided on the pixel layer.

The functional layer includes a light extraction structure GCQ, a first touch metal structure M1, and a second touch metal structure M2.

The light extraction structure is provided on the encapsulation layer, a projection of the light extraction structure on the substrate layer covers a projection of the light-emitting unit on the substrate layer, the light extraction structure is covered with a first insulating material OC1, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material.

The filter layer includes: a Color Filter (CF), and a Black Matrix (BM).

A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and the color filter and the black matrix are both covered with a second insulating material OC2.

The light extraction structure has a convex structure, a cross section of which in an embodiment of the present disclosure is schematically a trapezoidal structure. A convex direction of the convex structure faces the filter layer, adjacent light extraction structures are independent from each other, and the projection of the color filter on the substrate layer covers the projection of the light extraction structure on the substrate layer. That is, a projection of a first surface of the light extraction structure in contact with the encapsulation layer on the substrate layer is greater than a projection of a second surface (a surface parallel to the first surface) of the light extraction structure in contact with the first insulating material on the substrate layer.

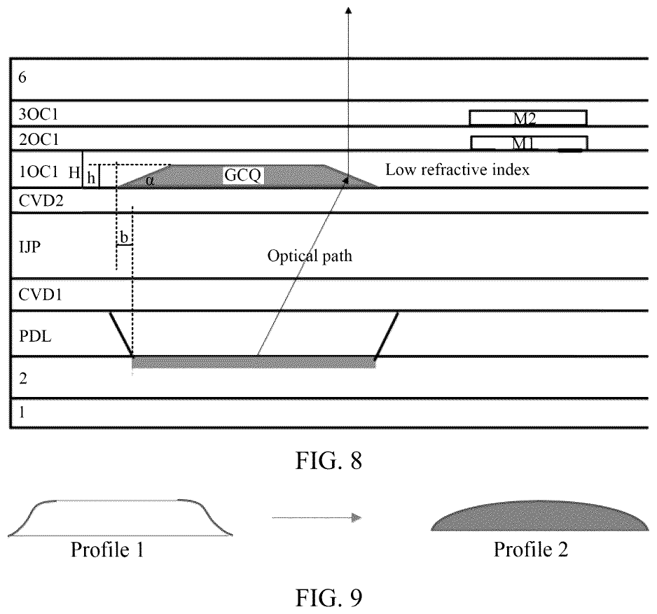

When the convex structure is a trapezoidal structure in the embodiment of the present disclosure, as shown in FIG. 8, structural parameters of the convex structure have following rules: 80°>α>50°, and b>0 um (that is, the light extraction structure needs to be outwardly expanded compared with an opening of the PDL). When viewing from the filter layer towards the substrate layer, the light extraction structure needs to be outwardly expanded at an equal distance compared with the opening of the pixel defining layer (PDL). Of course, in actual production, due to Overlay (deviation in the process) and other reasons, it is difficult for actual products to achieve completely equal distance, this actual situation will not be considered here. A thickness h of the light extraction structure mainly limits coverage on the light extraction structure by the first insulating material, that is, a thickness H of the first insulating material covering the light extraction structure should be greater than the thickness h of the light extraction structure. A value of h depends on the desired effect, and generally needs to be greater than 1 um.

After an actual process is completed, the cross-sectional profile of the light extraction structure is not a strict straight line, as shown in FIG. 9 in most cases. From a simulation perspective, to achieve superior light emission efficiency with less sacrifice in viewing angle (L-decay), a gentler arc profile 1 (profile 1, or profile 2) in the figure may be adopted. In embodiments of the present disclosure, simple geometric shapes such as straight lines or trapezoids are used to represent profile 1 or profile 2.

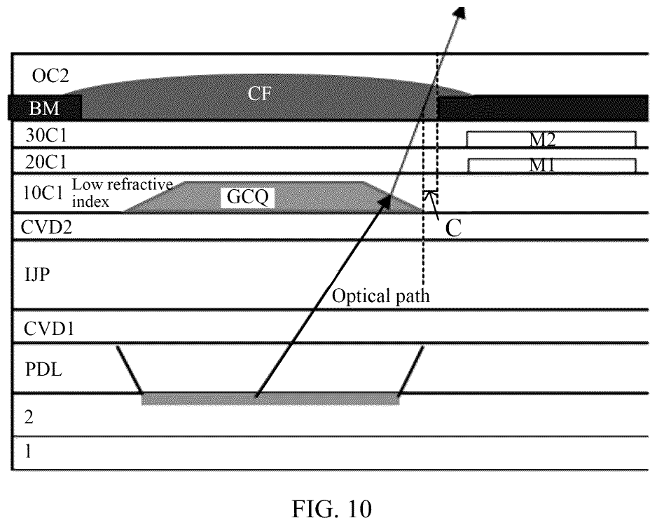

During design, it is also necessary to ensure that the projection of the black matrix on the substrate layer does not overlap with the projection of the light extraction structure on the substrate layer, as shown in FIG. 10, that is, to ensure that a value of C is greater than Oum, so as to ensure that deflected light which has a large angle before deflection and needs to be taken out is not absorbed by the black matrix (BM).

In the following embodiments, contents that need to be considered in the above design will not be repeated, and those skilled in the art may refer to the aforementioned embodiments.

Structures of the substrate layer, the pixel layer, and the drive circuit layer in FIG. 1 are the same as or similar to those of an existing display panel, and those skilled in the art may make adaptive design and adjustment according to actual needs. For example, the substrate layer may include a multilayer substrate. The drive circuit layer at least includes a first Planarization layer (PLN) 1, a second Planarization layer (PLN) 2, an InterLayer Dielectric layer (ILD), a first drive insulating layer (GI1, a second drive insulating layer (GI2, a first buffer layer (Buffer), and layers such as a gate (Gate), a source-drain layer (SD), and a polycrystalline silicon layer (active) provided among the above layers. Other layers such as the Gate of the drive circuit layer may be provided with reference to an existing structure, and will not be described here again.

The pixel layer includes a pixel defining layer (PDL) and a light-emitting unit (EL). The light-emitting unit includes structures such as an anode layer, a light-emitting material layer, and a cathode layer. The anode layer of the light-emitting unit is connected to a drive circuit of the drive circuit layer, and an encapsulation layer is provided on the cathode layer of the pixel layer.

The encapsulation layer includes a first vapor deposition layer (Chemical Vapor Deposition, CVD) 1, an ink-jet printing layer (Ink-Jet Printing, IJP), and a second vapor deposition layer (CVD2, which also has the same structure as an encapsulation layer of an existing display panel, and will also not be described here again.

It can be seen that the embodiment of the present disclosure provides a substrate layer, a drive circuit layer, a pixel layer, an encapsulation layer, a functional layer, and a filter layer in sequence from bottom to top.

For the first touch metal structure M1 and the second touch metal structure M2, for example, in a Flexible Multi-Layer On-Cell (FMLOC) structure, typically the second touch metal structure M2 includes first electrodes and second electrodes intersected with each other and insulated from each other, multiple first electrodes are directly connected in the second touch metal structure M2, and multiple second electrodes are connected through bridge electrodes of the first touch metal structure M1. The first touch metal structure M1 and the second touch metal structure M2 adopt a metal grid structure as a whole, and positions of the first touch metal structure M1 and the second touch metal structure M2 need to avoid the light-emitting unit when they are provided, so as to avoid affecting light emission of the light-emitting unit. Of course, the first touch metal structure M1 may be used as a first electrode and the second touch metal structure M2 may be used as a second electrode, and both adopt a metal grid structure as a whole. There is an overlapping portion between a projection direction of the first touch metal structure M1 and a projection direction of the second touch metal structure M2. During design, it is also necessary to avoid the light-emitting unit, so as to avoid affecting light emission of the light-emitting unit.

The insulating layer composed of the first insulating material in FIG. 1 includes three layers, namely, a first insulating layer, a second insulating layer, and a third insulating layer. The light extraction structure is provided in the first insulating layer 1OC1, the first touch metal structure is provided in the second insulating layer 2OC1, and the second touch metal structure is provided in the third insulating layer 3OC1. FIG. 1 is only an example, and does not limit the embodiments of the present disclosure. There are multiple possible implementations of the first insulating material, the light extraction structure, the metal structure, and the filter layer, which will be described in the following embodiments.

The functional layer of the embodiment of the present disclosure is provided with a light extraction structure, and a light refractive index of the light extraction structure is greater than a light refractive index of the first insulating material covering the light extraction structure thereon, thus an amount of light emitted from the light-emitting unit to the filter layer can be increased. In addition, the first insulating material covering a metal that realizes touch function is provided as an organic material, which can not only improve anti-compression and anti-bending capabilities of the display panel but also realize light refraction or reflection through a combination of a high-refractive index material of the light extraction structure and the organic material when the light extraction structure is provided in a corresponding functional layer where there has been the first insulating material. Compared with the existing process, it can significantly improve light emission efficiency of the display panel by adding only a Mask patterning step.

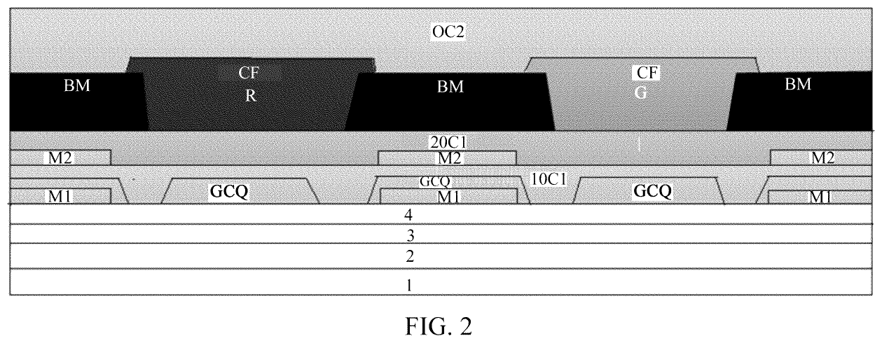

In the display panel shown in FIG. 1, a Mask step needs to be added compared with an existing process. In order to reduce preparation cost of the display panel and avoid deterioration of viewing angle (L-delay) caused by the black matrix (BM) being far away from the light-emitting unit (EL), an embodiment of the present disclosure further provides a display panel with a cross-sectional structure as shown in FIG. 2. Compared to the embodiment of FIG. 1, one Mask step is reduced in this structure. The display panel includes: a substrate layer 1, a drive circuit layer 2, a pixel layer 3, an encapsulation layer 4, a functional layer 5 and a filter layer 6.

The pixel layer includes a pixel defining layer (PDL) and a light-emitting unit (EL).

The light-emitting unit is connected to a drive circuit of the drive circuit layer, the drive circuit layer is provided on the substrate layer, and the encapsulation layer is provided on the pixel layer.

The functional layer includes a light extraction structure GCQ, a first touch metal structure M1, and a second touch metal structure M2.

The light extraction structure is provided on the encapsulation layer, a projection of the light extraction structure on the substrate layer covers a projection of the light-emitting unit on the substrate layer, the light extraction structure is covered with a first insulating material OC1, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material. The light extraction structure and the first touch metal structure are both provided in the first insulating layer 1OC1, and the second touch metal structure is provided in the second insulating layer 2OC1. A material used for the light extraction structure is covered on the first touch metal structure M1, that is, the projection of the light extraction structure on the substrate layer includes a projection of the first touch metal structure M1 on the substrate layer. The first insulating layer and the second insulating layer are both composed of the first insulating material.

The filter layer includes a color filter (CF) and a black matrix (BM).

A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and both the color filter and the black matrix are covered with a second insulating material OC2.

The light extraction structure has a convex structure, a cross section of which in an embodiment of the present disclosure is schematically a trapezoidal structure. A convex direction of the convex structure faces the filter layer, adjacent light extraction structures are independent from each other, and the projection of the color filter on the substrate layer covers the projection of the light extraction structure on the substrate layer. That is, a projection of a first surface of the light extraction structure in contact with the encapsulation layer on the substrate layer is greater than a projection of a second surface (a surface parallel to the first surface) of the light extraction structure in contact with the first insulating material on the substrate layer.

In a preparation process of the functional layer and the filter layer of the embodiment of the present disclosure, they may be prepared according to the following process: first touch metal structure M1→light extraction structure GCQ→first insulating layer 1OC1→second touch metal structure M2→second insulating layer 2OC1→black matrix BM→color filter CF (R/G/B)→second insulating material OC2. The first touch metal structure M1 is wrapped by the light extraction structure GCQ to prevent the first touch metal structure M1 from being corroded by a developer during development of the light extraction structure GCQ, thereby protecting the first touch metal structure M1 from being damaged.

The functional layer of the embodiment of the present disclosure is provided with a light extraction structure, and a light refractive index of the light extraction structure is larger than a light refractive index of the first insulating material covering the light extraction structure thereon, thus an amount of light emitted from the light-emitting unit to the filter layer can be increased. In addition, the first insulating material covering a metal that realizes touch function is provided as an organic material, which can not only improve anti-compression and anti-bending capabilities of the display panel but also realize light refraction or reflection through a combination of a high-refractive index material of the light extraction structure and the organic material when the light extraction structure is provided in a corresponding functional layer where there has been the first insulating material. Compared with the existing process, it can significantly improve light emission efficiency and viewing angle of the display panel without increasing a Mask step thereto.

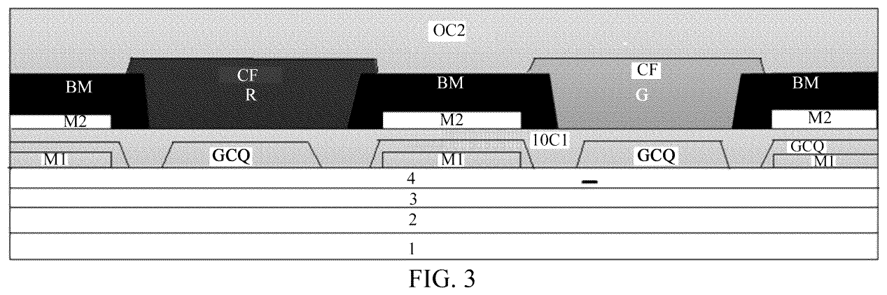

In the display panel shown in FIG. 1, a Mask step needs to be added compared with an existing process. In order to reduce preparation cost of the display panel and avoid deterioration of L-delay caused by the black matrix (BM) being far away from the light-emitting unit (EL), an embodiment of the present disclosure further provides a display panel with a cross-sectional structure as shown in FIG. 3. Compared to the embodiment of FIG. 1, in this structure two Mask steps are reduced. The display panel includes: a substrate layer 1, a drive circuit layer 2, a pixel layer 3, an encapsulation layer 4, a functional layer 5 and a filter layer 6.

The pixel layer includes a pixel defining layer (PDL) and a light-emitting unit (EL).

The light-emitting unit is connected to a drive circuit of the drive circuit layer, the drive circuit layer is provided on the substrate layer, and the encapsulation layer is provided on the pixel layer.

The functional layer includes a light extraction structure GCQ, a first touch metal structure M1, and a second touch metal structure M2.

The light extraction structure is provided on the encapsulation layer, a projection of the light extraction structure on the substrate layer covers a projection of the light-emitting unit on the substrate layer, the light extraction structure is covered with a first insulating material OC1, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material. The light extraction structure and the first touch metal structure are both provided in the first insulating layer 1OC1, and the second touch metal structure is provided on the first insulating layer 1OC1. The black matrix is covered on the second touch metal structure M2, and a material used for the light extraction structure is covered on the first touch metal structure M1. The first insulating layer is composed of the first insulating material.

The filter layer includes a Color Filter (CF) and a Black Matrix (BM).

A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and both the color filter and the black matrix are covered with a second insulating material OC2.

The light extraction structure has a convex structure, a cross section of which in an embodiment of the present disclosure is schematically a trapezoidal structure. A convex direction of the convex structure faces the filter layer, adjacent light extraction structures are independent from each other, and the projection of the color filter on the substrate layer covers the projection of the light extraction structure on the substrate layer. That is, a projection of a first surface of the light extraction structure in contact with the encapsulation layer on the substrate layer is greater than a projection of a second surface (a surface parallel to the first surface) of the light extraction structure in contact with the first insulating material on the substrate layer.

In a preparation process of the functional layer and the filter layer of the embodiment of the present disclosure, they may be prepared according to the following process: first touch metal structure M1→light extraction structure GCQ→first insulating layer 1OC1→second touch metal structure M2→black matrix BM→color filter CF (R/G/B)→second insulating material OC2. The first touch metal structure M1 is wrapped by the light extraction structure GCQ to prevent the first touch metal structure M1 from being corroded by a developer during development of the light extraction structure GCQ, thereby protecting the first touch metal structure M1 from being damaged.

The functional layer of the embodiment of the present disclosure is provided with a light extraction structure, and a light refractive index of the light extraction structure is greater than a light refractive index of the first insulating material covering the light extraction structure thereon, thus an amount of light emitted from the light-emitting unit to the filter layer can be increased. In addition, the first insulating material covering a metal that realizes touch function is provided as an organic material, it can not only improve anti-compression and anti-bending capabilities of the display panel but also realize light refraction or reflection through a combination of a high-refractive-index material of the light extraction structure and the organic material when the light extraction structure is provided in a corresponding functional layer where there has been the first insulating material. Compared with the existing process, one mask step is reduced, and it can significantly improve light emission efficiency and viewing angle of the display panel.

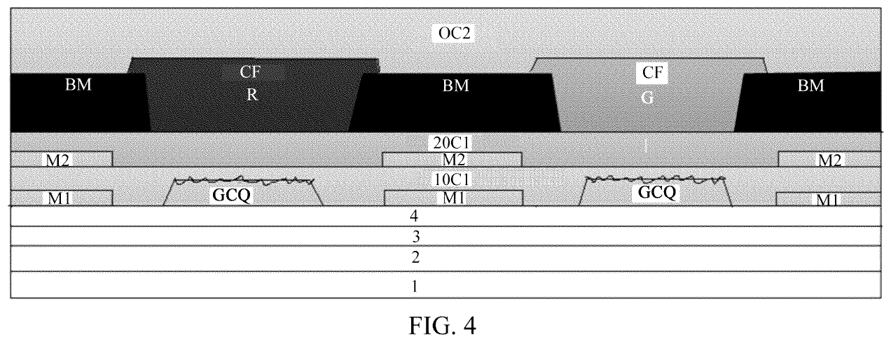

In the display panel shown in FIG. 1, a Mask step needs to be added compared with an existing process. In order to reduce preparation cost of the display panel and avoid deterioration of L-delay caused by the black matrix (BM) being far away from the light-emitting unit (EL), an embodiment of the present disclosure further provides a display panel with a cross-sectional structure as shown in FIG. 4. Compared to the embodiment of FIG. 1, in this structure one Mask step is reduced. The display panel includes: a substrate layer 1, a drive circuit layer 2, a pixel layer 3, an encapsulation layer 4, a functional layer 5 and a filter layer 6.

The pixel layer includes a pixel defining layer (PDL) and a light-emitting unit (EL).

The light-emitting unit is connected to a drive circuit of the drive circuit layer, the drive circuit layer is provided on the substrate layer, and the encapsulation layer is provided on the pixel layer.

The functional layer includes a light extraction structure GCQ, a first touch metal structure M1, and a second touch metal structure M2.

The light extraction structure is provided on the encapsulation layer, a projection of the light extraction structure on the substrate layer covers a projection of the light-emitting unit on the substrate layer, the light extraction structure is covered with a first insulating material OC1, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material. The light extraction structure and the first touch metal structure are both provided in the first insulating layer 1OC1, and the second touch metal structure is provided in the second insulating layer 2OC1. The first insulating material OC1 is covered on the first touch metal structure M1, and a surface of the light extraction structure in contact with the first insulating material is provided with a predetermined pattern (a concave-convex texture pattern schematically in the embodiment of the present disclosure). The first insulating layer and the second insulating layer are both composed of the first insulating material.

The filter layer includes a Color Filter (CF) and a Black Matrix (BM).

A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and both the color filter and the black matrix are covered with a second insulating material OC2.

The light extraction structure has a convex structure, a cross section of which in an embodiment of the present disclosure is schematically a trapezoidal structure. A convex direction of the convex structure faces the filter layer, adjacent light extraction structures are independent from each other, and the projection of the color filter on the substrate layer covers the projection of the light extraction structure on the substrate layer. That is, a projection of a first surface of the light extraction structure in contact with the encapsulation layer on the substrate layer is greater than a projection of a second surface (a surface parallel to the first surface) of the light extraction structure in contact with the first insulating material on the substrate layer.

In a preparation process of the functional layer and the filter layer of the embodiment of the present disclosure, they may be prepared according to the following process: light extraction structure GCQ→first touch metal structure M1→first insulating layer 1OC1→second touch metal structure M2→second insulating layer 2OC1→black matrix BM→color filter CF (R/G/B)→second insulating material OC2. The light extraction structure GCQ is etched into a concave-convex texture pattern, which can further disperse light coming out of the light-emitting unit and improve the L-delay.

The functional layer of the embodiment of the present disclosure is provided with a light extraction structure, and a light refractive index of the light extraction structure is greater than a light refractive index of the first insulating material covering the light extraction structure thereon, thus, an amount of light emitted from the light-emitting unit to the filter layer can be increased. In addition, the first insulating material covering a metal that realizes touch function is provided as an organic material, it can not only improve anti-compression and anti-bending capabilities of the display panel but also realize light refraction or reflection through a combination of a high-refractive-index material of the light extraction structure and the organic material when the light extraction structure is provided in a corresponding functional layer where there has been the first insulating material. Compared with the existing process, it can significantly improve light emission efficiency and viewing angle of the display panel without increasing a Mask step thereto.

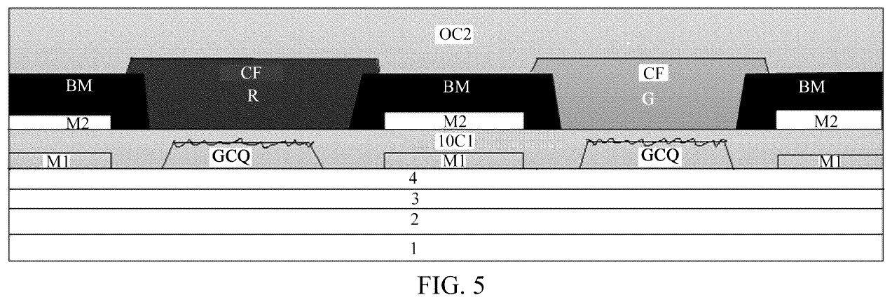

In the display panel shown in FIG. 1, a Mask step needs to be added compared with an existing process. In order to reduce preparation cost of the display panel and avoid deterioration of L-delay caused by the black matrix (BM) being far away from the light-emitting unit (EL), an embodiment of the present disclosure further provides a display panel with a cross-sectional structure as shown in FIG. 5. Compared to the embodiment of FIG. 1, in this structure two Mask steps are reduced. The display panel includes: a substrate layer 1, a drive circuit layer 2, a pixel layer 3, an encapsulation layer 4, a functional layer 5 and a filter layer 6.

The pixel layer includes a pixel defining layer (PDL) and a light-emitting unit (EL).

The light-emitting unit is connected to a drive circuit of the drive circuit layer, the drive circuit layer is provided on the substrate layer, and the encapsulation layer is provided on the pixel layer.

The functional layer includes a light extraction structure GCQ, a first touch metal structure M1, and a second touch metal structure M2.

The light extraction structure is provided on the encapsulation layer, a projection of the light extraction structure on the substrate layer covers a projection of the light-emitting unit on the substrate layer, the light extraction structure is covered with a first insulating material OC1, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material. The light extraction structure and the first touch metal structure are both provided in the first insulating layer 1OC1, and the second touch metal structure is provided on the first insulating layer 1OC1. The black matrix is covered on the second touch metal structure M2, and the first insulating material OC1 is covered on the first touch metal structure M1. A surface of the light extraction structure in contact with the first insulating material is provided with a predetermined pattern (a concave-convex texture pattern schematically in the embodiment of the present disclosure). The first insulating layer is composed of the first insulating material.

The filter layer includes a Color Filter (CF) and a Black Matrix (BM).

A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and the color filter and the black matrix are both covered with a second insulating material OC2.

The light extraction structure has a convex structure, a cross section of which in an embodiment of the present disclosure is schematically a trapezoidal structure. A convex direction of the convex structure faces the filter layer, adjacent light extraction structures are independent from each other, and the projection of the color filter on the substrate layer covers the projection of the light extraction structure on the substrate layer. That is, a projection of a first surface of the light extraction structure in contact with the encapsulation layer on the substrate layer is greater than a projection of a second surface (a surface parallel to the first surface) of the light extraction structure in contact with the first insulating material on the substrate layer.

In a preparation process of the functional layer and the filter layer of the embodiment of the present disclosure, they may be prepared according to the following process: light extraction structure GCQ→first touch metal structure M1→first insulating layer 1OC1→second touch metal structure M2→black matrix BM→color filter CF (R/G/B)→second insulating material OC2. The light extraction structure GCQ is etched into a concave-convex texture pattern, which can further disperse light coming out of the light-emitting unit and improve the L-delay.

The functional layer of the embodiment of the present disclosure is provided with a light extraction structure, and a light refractive index of the light extraction structure is greater than a light refractive index of the first insulating material covering the light extraction structure thereon, thus an amount of light emitted from the light-emitting unit to the filter layer can be increased. In addition, the first insulating material covering a metal that realizes touch function is provided as an organic material, it can not only improve anti-compression and anti-bending capabilities of the display panel but also realize light refraction or reflection through a combination of a high-refractive-index material of the light extraction structure and the organic material when the light extraction structure is provided in a corresponding functional layer where there has been the first insulating material. Compared with the existing process, one mask step is reduced, and it can further significantly improve light emission efficiency and viewing angle of the display panel.

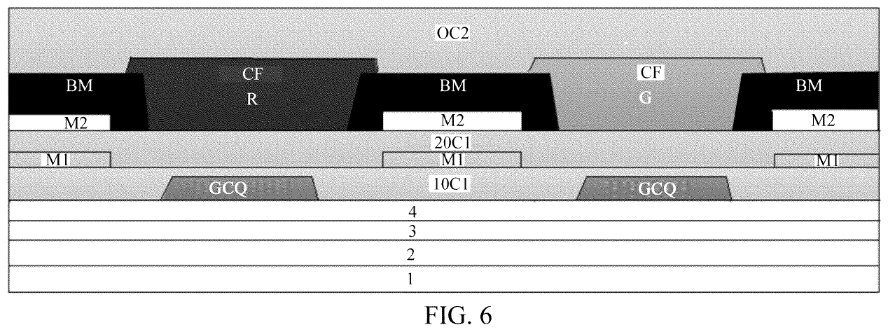

In the display panel shown in FIG. 1, a Mask step needs to be added compared with an existing process. In order to reduce preparation cost of the display panel and avoid deterioration of L-delay caused by the black matrix (BM) being far away from the light-emitting unit (EL), an embodiment of the present disclosure provides a display panel with a cross-sectional structure as shown in FIG. 6. The display panel includes: a substrate layer 1, a drive circuit layer 2, a pixel layer 3, an encapsulation layer 4, a functional layer 5 and a filter layer 6.

The pixel layer includes a pixel defining layer (PDL) and a light-emitting unit (EL).

The light-emitting unit is connected to a drive circuit of the drive circuit layer, the drive circuit layer is provided on the substrate layer, and the encapsulation layer is provided on the pixel layer.

The functional layer includes a light extraction structure GCQ, a first touch metal structure M1, and a second touch metal structure M2.

The light extraction structure is provided on the encapsulation layer, a projection of the light extraction structure on the substrate layer covers a projection of the light-emitting unit on the substrate layer, the light extraction structure is covered with a first insulating material OC1, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material. The light extraction structure GCQ is provided in the first insulating layer 1OC1, the first touch metal structure M1 is provided in the second insulating layer 2OC1, the second touch metal structure M2 is provided on the second insulating layer 2OC1, and the black matrix BM is covered on the second touch metal structure M2. The first insulating layer and the second insulating layer are composed of the first insulating material.

The filter layer includes a color filter (CF) and a black matrix (BM).

A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and both the color filter and the black matrix are covered with a second insulating material OC2.

The first insulating material shown in FIG. 6 includes two layers: a first insulating layer and a second insulating layer. When implemented, FIG. 6 may be improved with reference to the technical solution in the aforementioned embodiments, and the first insulating material may include only one first insulating layer, that is, the light extraction structure and the first touch metal structure are provided in a same layer. The detailed arrangement implementation may be referred to the aforementioned embodiments, and will not be repeated here.

The light extraction structure has a convex structure, a cross section of which in an embodiment of the present disclosure is schematically a trapezoidal structure. A convex direction of the convex structure faces the filter layer, adjacent light extraction structures are independent from each other, and the projection of the color filter on the substrate layer covers the projection of the light extraction structure on the substrate layer. That is, a projection of a first surface of the light extraction structure in contact with the encapsulation layer on the substrate layer is greater than a projection of a second surface (a surface parallel to the first surface) of the light extraction structure in contact with the first insulating material on the substrate layer.

The functional layer of the embodiment of the present disclosure is provided with a light extraction structure, and a light refractive index of the light extraction structure is greater than a light refractive index of the first insulating material covering the light extraction structure thereon, thus an amount of light emitted from the light-emitting unit to the filter layer can be increased. In addition, the first insulating material covering a metal that realizes touch function is provided as an organic material, it can not only improve anti-compression and anti-bending capabilities of the display panel but also realize light refraction or reflection through a combination of a high-refractive-index material of the light extraction structure and the organic material when the light extraction structure is provided in a corresponding functional layer where there has been the first insulating material. Compared with the existing process, it can significantly improve light emission efficiency and viewing angle of the display panel without increasing a Mask step thereto or even by reducing a Mask step.

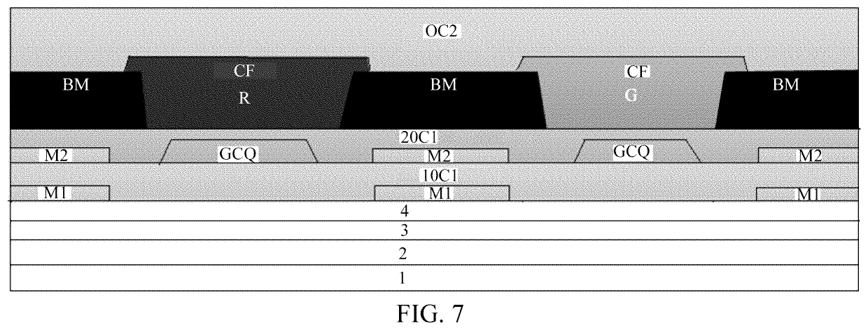

In the display panel shown in FIG. 1, a Mask step needs to be added compared with an existing process. In order to reduce preparation cost of the display panel and avoid deterioration of L-delay caused by the black matrix (BM) being far away from the light-emitting unit (EL), an embodiment of the present disclosure provides a display panel with a cross-sectional structure as shown in FIG. 7. The display panel includes: a substrate layer 1, a drive circuit layer 2, a pixel layer 3, an encapsulation layer 4, a functional layer 5 and a filter layer 6.

The pixel layer includes a pixel defining layer (PDL) and a light-emitting unit (EL).

The light-emitting unit is connected to a drive circuit of the drive circuit layer, the drive circuit layer is provided on the substrate layer, and the encapsulation layer is provided on the pixel layer.

The functional layer includes a light extraction structure GCQ, a first touch metal structure M1, and a second touch metal structure M2.

The light extraction structure is provided on the encapsulation layer, a projection of the light extraction structure on the substrate layer covers a projection of the light-emitting unit on the substrate layer, the light extraction structure is covered with a first insulating material OC1, and a light refractive index of the light extraction structure is greater than a light refractive index of the first insulating material. A projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material. The first touch metal structure M1 is provided in the first insulating layer 1OC1, and the light extraction structure GCQ and the second touch metal structure M2 are both provided in the second insulating layer 2OC1. The first insulating layer and the second insulating layer are both composed of the first insulating material.

The filter layer includes a color filter (CF) and a black matrix (BM).

A projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and both the color filter and the black matrix are covered with a second insulating material OC2.

The light extraction structure has a convex structure, a cross section of which in an embodiment of the present disclosure is schematically a trapezoidal structure. A convex direction of the convex structure faces the filter layer, adjacent light extraction structures are independent from each other, and the projection of the color filter on the substrate layer covers the projection of the light extraction structure on the substrate layer. That is, a projection of a first surface of the light extraction structure in contact with the encapsulation layer on the substrate layer is greater than a projection of a second surface (a surface parallel to the first surface) of the light extraction structure in contact with the first insulating material on the substrate layer.

The functional layer of the embodiment of the present disclosure is provided with a light extraction structure, and a light refractive index of the light extraction structure is greater than a light refractive index of the first insulating material covering the light extraction structure thereon, thus, an amount of light emitted from the light-emitting unit to the filter layer can be increased. In addition, the first insulating material covering a metal that realizes touch function is provided as an organic material, it can not only improve anti-compression and anti-bending capabilities of the display panel but also realize light refraction or reflection through a combination of a high-refractive-index material of the light extraction structure and the organic material when the light extraction structure is provided in a corresponding functional layer where there has been the first insulating material. Compared with the existing process, it can significantly improve light emission efficiency and viewing angle of the display panel without increasing a Mask step thereto or even by reducing a Mask step.

The aforementioned embodiments are only examples of the embodiment solutions of the present disclosure, and when implementing them, those skilled in the art may adaptively adjust the aforementioned embodiments. For example, the light extraction structure has a convex structure, however direction and structure of the convex structure thereof is changed, such that a convex direction of the convex structure faces the encapsulation layer, adjacent light extraction structures are connected to each other to form a continuous light extraction structure, and a surface of the continuous light extraction structure in contact with the first insulating material is parallel to a first surface (a surface close to the filter layer) of the encapsulation layer.

At present, there are still some problems of pin protection. Therefore, in the embodiments of the present disclosure, before the functional layer is prepared, an inorganic layer is first made for protection, that is, an inorganic layer is further provided on the encapsulation layer, and then a functional layer is provided on the inorganic layer, so as to solve the problem that the pin needs to be protected.

It can be seen that embodiments of the present disclosure have multiple structural variations, which are not described one by one herein, but all of them are within the protection scope of the embodiments of the present disclosure.

An embodiment of the present disclosure further provides an electronic device, which may include the display panel in any embodiment of the present disclosure, and a structure of the display panel is not described here.

In addition, although the exemplary embodiments have been described herein, their scope includes any and all embodiments having equivalent elements, modifications, omissions, combinations (e.g., solutions formed among various embodiments), adaptations or changes based on the present disclosure. Elements in the claims will be broadly interpreted on the basis of the language used in the claims, and are not limited to the examples described in this specification or during the implementation of the present disclosure, and the examples thereof will be interpreted to be non-exclusive. Therefore, this specification and the examples are intended to be considered to be exemplary only, and the true scope and essence will be indicated by the full range of the following claims and equivalents thereof.

The above description is intended to be illustrative and not limiting. For example, the above examples (or one or more solutions thereof) may be used in combination with each other. For example, other embodiments may be used by those of ordinary skills in the art upon reading the above description. In addition, in the above embodiments, various features may be grouped together to simplify the present disclosure, which should not be interpreted as an intention that an unclaimed disclosed feature is essential for any claim. On the contrary, the subject matter of the present disclosure may be less than all features of a particular disclosed embodiment. Therefore, the following claims are hereby incorporated into the embodiments as examples or embodiments, wherein each claim is independently used as a separate embodiment, and it is considered that these embodiments may be combined with each other in various combinations or arrangements. The scope of the present disclosure should be determined with reference to the full scope of the appended claims and equivalents to which these claims are entitled.

Multiple embodiments of the present disclosure are specifically described above but not intended to limit the present disclosure. Those skilled in the art may make various transformations and modifications based on the concept of the present disclosure. These transformations and modifications shall fall in the scope of protection of the present disclosure.

1. A display panel, comprising:
a substrate layer, a drive circuit layer, a pixel layer, an encapsulation layer, a functional layer and a filter layer, wherein,
the pixel layer comprises a pixel defining layer and a light-emitting unit;
the light-emitting unit is connected to a drive circuit of the drive circuit layer, the drive circuit layer is provided on the substrate layer, and the encapsulation layer is provided on the pixel layer;
the functional layer comprises a light extraction structure, a first touch metal structure, and a second touch metal structure;
the light extraction structure is provided on the encapsulation layer, a projection of the light extraction structure on the substrate layer covers a projection of the light-emitting unit on the substrate layer, the light extraction structure is covered with a first insulating material, and a light refractive index of the light extraction structure is greater than a light refractive index of the first insulating material; and a projection of the first touch metal structure on the substrate layer at least partially overlaps with a projection of the second touch metal structure on the substrate layer, the first touch metal structure is away from the filter layer, the second touch metal structure is close to the filter layer, at least the first insulating material is provided between the first touch metal structure and the second touch metal structure, and the first insulating material is an organic material;
the filter layer comprises a color filter and a black matrix; and
a projection of the color filter on the substrate layer covers the projection of the light-emitting unit on the substrate layer, the black matrix is provided adjacent to the color filter, a projection of the black matrix on the substrate layer covers the projection of the second touch metal structure on the substrate layer, and the color filter and the black matrix are covered with a second insulating material.

2. The display panel according to claim 1, wherein
the light extraction structure is provided in a first insulating layer, the first touch metal structure is provided in a second insulating layer, and the second touch metal structure is provided in a third insulating layer, wherein the first insulating layer, the second insulating layer, and the third insulating layer are all formed by the first insulating material.

3. The display panel according to claim 1, wherein
the light extraction structure is provided in a first insulating layer, the first touch metal structure is provided in a second insulating layer, the second touch metal structure is provided on the second insulating layer, and the black matrix is covered on the second touch metal structure, wherein the first insulating layer and the second insulating layer are both formed by the first insulating material.

4. The display panel according to claim 1, wherein
the first touch metal structure is provided in a first insulating layer, and the light extraction structure and the second touch metal structure are both provided in a second insulating layer, wherein the first insulating layer and the second insulating layer are both formed by the first insulating material.

5. The display panel according to claim 1, wherein
the light extraction structure and the first touch metal structure are both provided in a first insulating layer, and the second touch metal structure is provided in a second insulating layer, wherein the first insulating layer and the second insulating layer are both formed by the first insulating material.

6. The display panel according to claim 1, wherein
the light extraction structure and the first touch metal structure are both provided in a first insulating layer, the second touch metal structure is provided on the first insulating layer, and the black matrix is covered on the second touch metal structure, wherein the first insulating layer is formed by the first insulating material.

7. The display panel according to claim wherein
a material used by the light extraction structure is covered on the first touch metal structure.

8. The display panel according to claim wherein
the first insulating material is covered on the first touch metal structure, and a surface of the light extraction structure in contact with the first insulating material is provided with a predetermined pattern.

9. The display panel according to claim 2, wherein
an inorganic layer is further provided on the encapsulation layer.

10. The display panel according to claim 2, wherein
the light extraction structure has a convex structure, a convex direction of the convex structure faces the filter layer, adjacent light extraction structures are independent from each other, and the projection of the color filter on the substrate layer covers the projection of the light extraction structure on the substrate layer.

11. The display panel according to claim 2, wherein
the light extraction structure has a convex structure, a convex direction of the convex structure faces the encapsulation layer, adjacent light extraction structures are connected to each other to form a continuous light extraction structure, a surface of the continuous light extraction structure in contact with the first insulating material is parallel to a first surface of the encapsulation layer, wherein the first surface is a surface close to the filter layer.

12. The display panel according to claim 1, wherein
the light extraction structure has a convex structure, a cross section of the convex structure is a trapezoid, and a bottom angle of the trapezoid is greater than 50 degrees and less than 80 degrees.

13. The display panel according to claim 1, wherein
the projection of the light extraction structure on the substrate layer is greater than a projection of an opening of the pixel defining layer on the substrate layer.

14. The display panel according to claim 1, wherein
a projection of the black matrix on the substrate layer does not overlap with the projection of the light extraction structure on the substrate layer.

15. An electronic device, comprising the display panel according to claim 1.

16. The display panel according to claim 6, wherein
the first insulating material is covered on the first touch metal structure, and a surface of the light extraction structure in contact with the first insulating material is provided with a predetermined pattern.

17. The display panel according to claim 3, wherein
the light extraction structure has a convex structure, a convex direction of the convex structure faces the filter layer, adjacent light extraction structures are independent from each other, and the projection of the color filter on the substrate layer covers the projection of the light extraction structure on the substrate layer.

18. The display panel according to claim 4, wherein
the light extraction structure has a convex structure, a convex direction of the convex structure faces the filter layer, adjacent light extraction structures are independent from each other, and the projection of the color filter on the substrate layer covers the projection of the light extraction structure on the substrate layer.

19. The display panel according to claim 5, wherein
the light extraction structure has a convex structure, a convex direction of the convex structure faces the filter layer, adjacent light extraction structures are independent from each other, and the projection of the color filter on the substrate layer covers the projection of the light extraction structure on the substrate layer.

20. The display panel according to claim 6, wherein
the light extraction structure has a convex structure, a convex direction of the convex structure faces the filter layer, adjacent light extraction structures are independent from each other, and the projection of the color filter on the substrate layer covers the projection of the light extraction structure on the substrate layer.
